(19) United States
(12) Patent Application Publication
(10) Pub. No.: US 2026/0173798 A1
(43) Pub. Date: Jun. 18, 2026

(54) ONE-DIMENSIONAL IMAGE SENSOR ARRAY

(71) Applicant: ASM IP Holding B.V., Almere (NL)

(72) Inventors: Samer Banna, Phoenix, AZ (US); Masaei Suwada, Nagaoka-shi (JP); Masaki Shimomura, Tokyo (JP); Masashi Nakano, Tokyo (JP); Taira Okabe, Kawasaki-shi (JP)

(21) Appl. No.: 19/413,156

(22) Filed: Dec. 9, 2025

Related U.S. Application Data
(60) Provisional application No. 63/733,346, filed on Dec. 12, 2024.

(51) Int. Cl. H10P 72/00; H10P 72/10; H10P 72/50; H10P 72/76; H10P 74/00; H10P 74/20

(52) U.S. Cl. CPC H10P 72/0604; H10P 72/0454; H10P 72/0602; H10P 72/10; H10P 72/50; H10P 72/7602; H10P 74/203; H10P 74/238

(57) ABSTRACT

A system and a process for monitoring substrates is disclosed. The system and process may include a gate valve, a robot configured to transfer a substrate from a first chamber to a second chamber through the gate valve, and a sensor array aligned with the gate valve. The sensor array may be configured to capture data of the substrate along a single dimension when the substrate is moved in view of the sensor array. The system and process may assist to provide a less complex and less time consuming way to fully inspect a wafer.

### CROSS-REFERENCE TO RELATED APPLICATIONS

This application claims priority to U.S. Provisional Patent Application Ser. No. 63/733,346 filed Dec. 12, 2024 titled ONE-DIMENSIONAL IMAGE SENSOR ARRAY, the disclosure of which is hereby incorporated by reference in its entirety.

### FIELD OF INVENTION

The present disclosure generally relates to fabricating semiconductor devices.

### BACKGROUND OF THE DISCLOSURE

A process of using a substrate processing apparatus includes a step of transporting a substrate from a Front Opening Unified Pod (FOUP) to a processing chamber via a substrate handling chamber and a load lock chamber using a robotic arm, or a step of transporting a substrate from a reaction chamber to another reaction chamber using a robotic arm. The robotic arm may be provided with an end effector for loading a substrate thereon and carrying the substrate from one chamber to another.

Conventionally, substrates have to be inspected for any issues or problems that may affect the processing on a particular substrate. However, conventional sampling inspection often overlooks problematic wafers. Specifically, transferring the substrates to a specified location to capture a full view of the wafer affects throughput. Further, capturing an image with a two-dimensional camera requires uniform light conditions that may be time consuming and complex to set up. Such a manner of full inspection can be highly costly to implement.

Accordingly, there is a need in the industry to provide a less complex and less time consuming systems and methods of full wafer inspection. Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

In accordance with at least one embodiment of an invention, a substrate processing system is disclosed. The substrate processing system may comprise: at least one gate valve; at least one robot configured to transfer a substrate from one chamber to another through the at least one gate valve; and at least one sensor array aligned with the at least one gate valve, wherein the sensor array is configured to capture data of the substrate along a single dimension when the substrate is moved in view of the at least one sensor array.

In accordance with at least one embodiment of an invention, a method of measuring a state of a substrate in a substrate processing system is disclosed. The method comprises: providing at least one sensor array in at least one chamber of the substrate processing system; when the substrate passes under the at least one sensor array, capturing substrate data indicative of the state of the substrate at each coordinate at a given time; utilizing the coordinate data to determine the state of the substrate along a single dimension during a given time period; converting the substrate data received from each sensor in the at least one sensory array along the single dimension to determine the state of the substrate as a whole; and determining whether a condition should be altered based on the state of the substrate.

In accordance with at least one embodiment of an invention, a non-transitory computer-readable medium for determining state of a substrate transferring in a substrate processing system is disclosed. The non-transitory computer-readable medium comprises: receiving substrate data from a sensor array provided in at least one chamber of the substrate processing system, the substrate data indicative of the state of the substrate at each coordinate at a given time; determining the state of the substrate data along a single dimension during a given time period, the given time period include the given time; and extrapolating the substrate data received from each sensor in the at least one sensory array along the single dimension to determine a state of the substrate as a whole.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIGS. 1A-1B illustrates an overhead view of a substrate processing system in accordance with embodiments described herein;

FIG. 2 illustrates an exploded view of sensor measurement in process of a substrate in the substrate processing system of FIGS. 1A-1B in accordance with embodiments described herein;

FIG. 3 illustrates a flow diagram of a method of measuring the state of a substrate in a substrate processing system of FIG. 1 in accordance with embodiments described herein;

FIG. 4 illustrates a flow diagram of a method of determining state of a substrate transferring in a substrate processing system in accordance with embodiments described herein.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

Reference will now be made to the drawings wherein like reference numerals identify similar structural features or aspects of the subject disclosure. The systems and methods of the present disclosure may be in semiconductor processing systems employed to fabricate semiconductor devices, such as in semiconductor processing systems employed to deposit material layers using chemical vapor deposition (CVD) and atomic layer deposition (ALD) techniques during the fabrication of logic and memory devices, though the present disclosure is not limited to any semiconductor processing operation or to the fabrication of any particular semiconductor device in general.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Wafers may be 200 millimeters in diameter, 300 millimeters, or even 450 millimeters in diameter. Substrates may be formed from one or more semiconductor materials including by way of non-limiting example silicon, silicon germanium, silicon oxide, gallium arsenide, gallium nitride and silicon carbide.

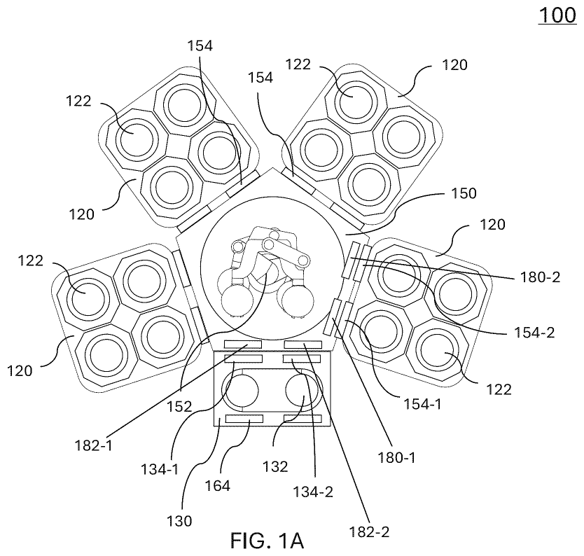

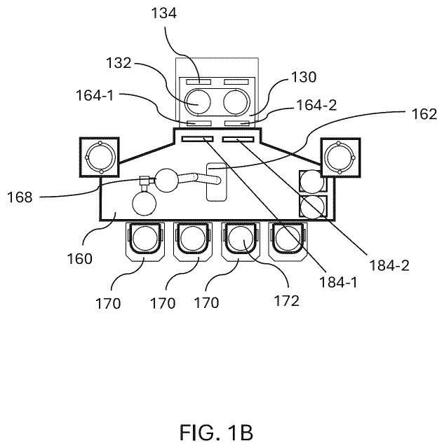

FIGS. 1A and 1B illustrates an overhead view of two different parts of a substrate processing system 100 in accordance with embodiments described herein. In the embodiment shown in FIG. 1A, the substrate processing system 100 may include a five faceted substrate handling chamber (SHC) 150 (although more or fewer facets could be provided in other examples of this technology). Four of these facets may be coupled to a plurality of respective substrate processing chambers (SPC) 120 via one or more gate valves 154. Further, each SPC may be equipped to receive and process at least four substrates (a plurality of substrate supports 122 are provided in the SPC 120).

The SHC 150 may include at least one robotic arm 152 that is used to move substrate into and out of the various SPCs 120. In use, after a gate valve 154 is opened, an end effector of the robotic arm 152 may extend through the open gate valve 154 to insert a substrate into or remove a substrate from an interior chamber of the SPC 120 (e.g. placing a substrate on or taking a substrate off one of the substrate supports 122). Once the robotic arm 152 is retracted from the SPC 120, the gate valve 154 may be closed, thereby sealing the SPC 120 from the gate valve 154.

The substrate processing system 100 further may include a load lock (LL) module 130 is connected with the fifth facet of the SHC 150 by one or more gate valves 134. The LL module 130 may include one or more substrate holders 132 for holding the substrate on the way into SHC 150 for further processing and on the way out of the SHC 150 after processing is complete. The end effector of the robotic arm 152 may move through the gate valves 134 (when opened) to move substrate into the SHC 150 (for layer deposition and other processing) and out of SHC 150 (after processing is completed).

As further shown in FIG. 1B, the LL module 130 may be further coupled with an equipment front end module (EFEM) 160 via one or more additional gate valves 164-1 and 164-2. The EFEM 160 further includes an EFEM robot 162. In exemplary embodiments, the EFEM robot 162 may be a dual arm robot with an upper arm 172. The upper arm 172 may move through the gate valve(s) 164 (when opened) to move substrate into the LL module 130 (to eventually transport to the processing chamber 120 for layer deposition and other processing) and out of the LL module 130 (after processing is completed). The robot 162 may be also configured to pick up new substrates for processing from one or more front opening unified pod (FOUP) 170 and returns processed substrates back to the FOUP 170. In exemplary embodiments, multiple FOUPs 170 may be included. In the example described herein, the four FOUPs 170 are coupled to the EFEM 160. Although shown and described herein as having a specific architecture, it is to be understood and appreciated that the substrate processing system 100 may have different architectures in other examples of the present disclosure (e.g. varying number of the FOUPs 170, the gate valves 134, 154, the chambers 120, etc.), and remain within the scope of the present disclosure.

In exemplary embodiments, semiconductor processing system may further include one or more sensor arrays to capture wafer data (for example, height of wafer, reflection rate of wafer, temperature data of wafer, etc.). These sensor arrays may be positioned along a transfer path of wafers so that the condition of wafer can be measured before or after processing.

In exemplary embodiment shown in FIG. 1B, a first sensor array 184-1 may be positioned in the EFEM 160 aligned with the gate valve 164-1. Accordingly, when the robot 162 carries substrates from the FOUP 170 to transfer to the LL 130, the first sensor array 184-1 may capture substrate data at given time intervals to obtain a complete picture of substrate health before it is transferred to the LL 130. A second sensor array 184-2 may be included to capture substrate data of substrates that are to transfer through the gate valve 164-2.

In exemplary embodiments, a third sensor array 182-1 and/or a fourth sensor array 182-2 may be positioned in the SHC 150 aligned with a plurality of gate valves 134-1 and 134-2, respectively. As the robot 152 lifts substrates from the LL 130 and carries into the SHC 150, the third sensor array 182-1 and/or the fourth sensor array 182-2 may capture substrate data of one or more substrates at given time intervals to obtain a complete picture of substrate health at the time it is received by the SHC 130.

In exemplary embodiments, a fifth sensor array 180-1 and/or a sixth sensor array 180-2 may be positioned in the SHC 150 aligned with a plurality of gate valves 154-1 and 154-2, respectively. As the robot 152 transfers substrates from the SHC 150 to the SPC 120, the fifth sensor array 180-1 and/or the sixth sensor array 180-2 may capture substrate date of one or more substrates at given time intervals to obtain a complete picture of substrate health at the time prior to transferring to the processing module 120. While the exemplary embodiment only depicts sensor array(s) along a single facet of the SHC 150, similar sensor arrays may be placed aligned with the respective gate valves 154 to measure substrate health prior to transfer to the processing module 120.

In exemplary embodiments, any of the sensor arrays 180, 182, 184 may be a 1D image sensor. The image sensors are configured to capture data along a single dimension, where the capture light may then be converted into electronic signals to create an image or measurement. In exemplary embodiments, the image captured by the sensor may be utilized to measure the state of the wafer as it moves through the gate valve. For example, each sensor can capture the position, orientation, height, and any potential defects on the wafer surface as it moves through a gate valve or other processing module.

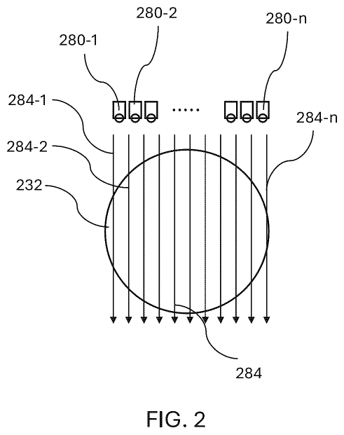

For example, an exploded view of sensor measurement in process is illustrated in FIG. 2. Each sensor array 180, 182, 184 may include individual sensors 280-1 to 280-n. As the substrate 234 passes through sensor array, each sensor array 280 captures data along a single dimension 284. That is, the sensor 280-1 captures data along dimension 284-1, the sensor 280-2 captures data along dimension 284-2 and so on. Thus, individual captures by each sensor 280 along a dimension 284 can then be utilized to provide a complete picture depicting the state of the substrate 232 as it passes through sensor array.

In exemplary embodiments, any of sensor array 180, 182, 184 may include laser temperature sensors configured to measure temperature data of a substrate along a single dimension as it passes through the sensor array 180, 182, 184. In exemplary embodiments, any of sensor array 180, 182, 184 may include laser depth sensor configured to measure reflection rate of the substrate along a single dimension as it passes through the sensor array 180, 182, 184 and reveal any inconsistencies in the texture of the wafer. Accordingly, a complete picture depicting state of the substrate may be provided as it passes through the sensor array.

In exemplary embodiments, all of the sensor arrays utilized in the processing system 100 may be the same. In exemplary embodiments, varied types of sensor arrays may be utilized. For example, the arrays 180, 182 and 184 may all be image sensor arrays. Alternatively, the array 180 may be image sensor array, the array 182 may be a temperature array, and the array 184 may be a depth array. Any other combinations may be utilized depending on the needs of the processing system 100.

The data received from the sensor arrays for each of the substrates may then be utilized for determining any changes to be made in process or environmental condition. For example, based on the health of the wafer, the process parameters may be altered to effectively deposit on a particular wafer. Similarly, transfer condition may also be changed based on the data received from the sensor array and the robot speed is adjusted.

In exemplary embodiments, the sensor arrays 180, 182, 184 may also be utilized to capture data of processed wafers after processing in the modules 120. That is, process quality from each of the chambers may be measured to determine, for example, process quality. Accordingly, the data received of the processed wafers may provide indication with respect to conditions within the processing module 120 and any changes that may need to be made in view of the state of the processed wafers. Similarly, as the processed wafers transfer through various chambers, the quality of the processed wafer may be determined using sensor arrays.

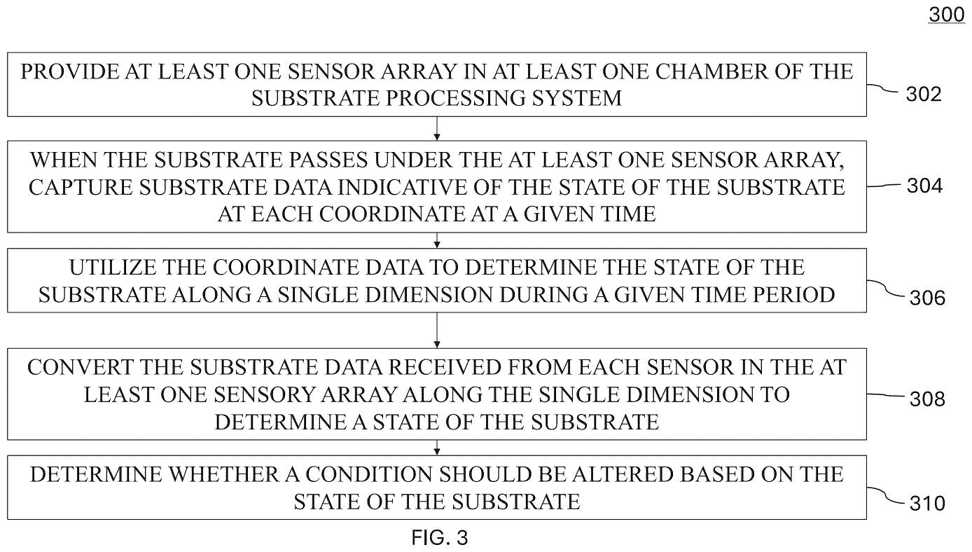

FIG. 3 illustrates a method 300 of measuring the state of a substrate in a substrate processing system. The method 300 includes providing at least one sensor array, such as the sensor array 180, 182, 184 in at least one chamber of the substrate processing system, such as the EFEM 160 or the SHC 150, as shown with a box 302. In exemplary embodiments of the method 300, the sensor array includes at least one of a 1D image sensor, a laser temperature sensor or a laser depth sensor. In exemplary embodiments, the sensor array is provided in an EFEM and is aligned with an EFEM gate valve, such as the gate valve 184. In exemplary embodiments, the sensor array is provided in a SHC and is aligned with a SHC gate valve. In exemplary embodiments, the sensor array is provided in a SHC and is aligned with a processing module gate valve. In exemplary embodiments, a plurality of sensor arrays may be provided.

When the substrate passes under the at least one sensor array, the method 300 further includes capturing substrate data indicative of the state of the substrate at each coordinate at a given time, as shown with a box 304. The method 300 further includes utilizing the coordinate data to determine the state of the substrate along a single dimension during a given time period, as shown with a box 306. In exemplary embodiments, substrate data is indicative of height of the substrate. In exemplary embodiments, substrate data is indicative of reflection rate of the substrate. In exemplary embodiments, substrate data is indicative of temperature of the substrate. In exemplary embodiments, the method 300 includes capturing substrate data after the substrate has been processed. Accordingly, in such exemplary embodiments, captured substrate data is indicative of the state of the processed substrate.

The method 300 further includes converting the substrate data received from each sensor in the at least one sensory array along the single dimension to determine the state of the substrate as a whole, as shown with a box 308. The method 300 further includes determining whether a condition should be altered based on the state of the substrate, as shown with a box 310. In exemplary embodiments, a process condition effected by the processing module is altered based on the state of the incoming substrate based on the captured data. In exemplary embodiments, a transfer condition is changed based on the state of the substrate. That is, in these exemplary embodiments, speed of at least one of the EFEM robot 162 or a SHC robot 152 may be adjusted when the substrate is transferred.

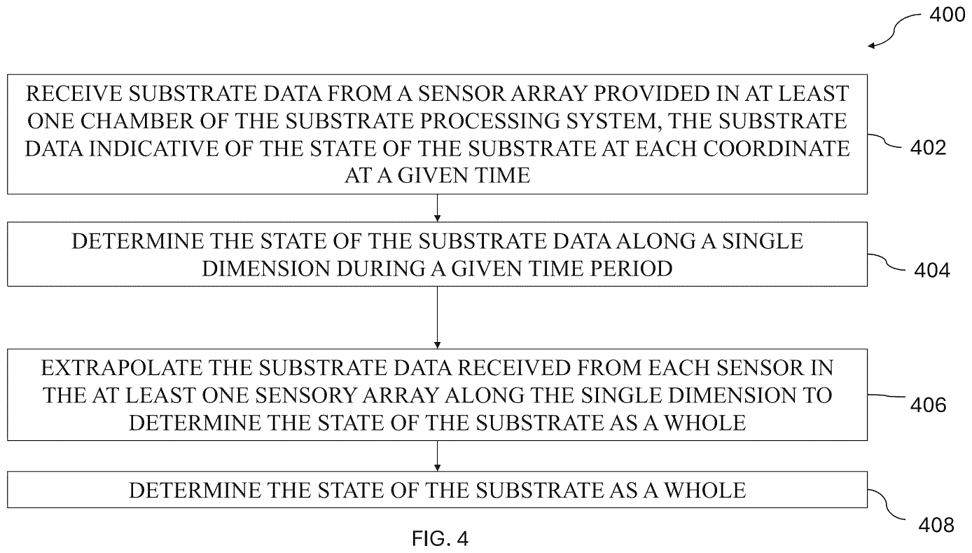

FIG. 4 illustrates a method 400 of determining state of a substrate transferring in a substrate processing system. The method 400 includes receiving substrate data from a sensor array, such as the sensor array 180, 182, 184 provided in at least one chamber of the substrate processing system, such as the EFEM 160 or the SHC 150, the substrate data indicative of the state of the substrate at each coordinate at a given time, as shown with a box 402. In exemplary embodiments, the sensor array includes at least one of a 1D image sensor, a laser temperature sensor or a laser depth sensor. In exemplary embodiments, the received substrate data is indicative of height of the substrate. In exemplary embodiments, the received substrate data is indicative of reflection rate of the substrate. In exemplary embodiments, the received substrate data is indicative of temperature of the substrate. In exemplary embodiments, a plurality of sensor arrays may be provided.

In exemplary embodiments, the sensor array is provided in an EFEM and is aligned with an EFEM gate valve, such as the gate valve 184, and the substrate data is indicative of the state of the substrate before the substrate transfers from an EFEM of the substrate processing system to a load lock chamber of the substrate processing system. In exemplary embodiments, the sensor array is provided in a SHC and is aligned with a SHC gate valve, such as the gate valve 134, and the substrate data is indicative of the state of the substrate before the substrate transfers from the load lock chamber to a substrate handling chamber of the substrate processing system. In exemplary embodiments, the sensor array is provided in the SHC and is aligned with a processing module gate valve, such as the gate valve 154, and the substrate data is indicative of the state of the substrate before the substrate transfers from the substrate handling chamber to a processing module of the substrate processing system.

The method 400 further includes determining the state of the substrate data along a single dimension, as shown in FIG. 2, during a given time period, the given time period includes the given time, as shown in a box 404. The method 400 further includes extrapolating the substrate data received from each sensor in the at least one sensory array along the single dimension to determine the state of the substrate as a whole, as shown in a box 406. Finally, the method 400 includes determining the state of the substrate as a whole, as shown in a box 408. In exemplary embodiments, the method 400 further includes determining alteration of a process condition based on the state of the substrate. In exemplary embodiments, the method 400 further includes determining adjustment of speed of at least one of an EFEM robot or a SHC robot based on the state of the substrate.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A substrate processing system comprises:
at least one gate valve;
at least one robot configured to transfer a substrate from a first chamber to a second chamber through the at least one gate valve; and
at least one sensor array aligned with the at least one gate valve, wherein the sensor array is configured to capture data of the substrate along a single dimension when the substrate is moved in view of the at least one sensor array.

2. The substrate processing system of claim 1, wherein the substrate processing system further comprises:
an equipment front end module (EFEM) comprising an EFEM robot;
a front opening unified pod (FOUP); and
a load lock chamber;
wherein the at least one gate valve comprises at least one EFEM gate valve;
wherein the EFEM robot is configured to transfer the substrate between the FOUP and the load lock chamber via the at least one EFEM gate valve; and
wherein the at least one sensor array is positioned within the EFEM and aligned with the at least one EFEM gate valve to capture data from the substrate as it leaves or enters the load lock chamber.

3. The substrate processing system of claim 1, wherein the substrate processing system further comprises:
a load lock chamber; and
a substrate handling chamber (SHC) having a SHC robot; and
at least one processing module;
wherein the at least one gate valve comprises at least one SHC gate valve;
wherein the SHC robot is configured to transfer the substrate between load lock chamber and the processing module via the at least one SHC gate valve; and
wherein the at least one sensor array is positioned within the SHC and aligned with the at least one SHC gate valve to capture data from the substrate as it leaves or enters the load lock chamber.

4. The substrate processing system of claim 1, wherein the substrate processing system further comprises:
a substrate handling chamber (SHC) having a SHC robot; and
at least one processing module;
wherein the at least one gate valve comprises at least one process module gate valve;
wherein the SHC robot is configured to transfer the substrate between a load lock chamber and the processing module via the at least one process module gate valve; and
wherein the at least one sensor array is positioned within the SHC and aligned with the at least one process module gate valve to capture data from the substrate as it leaves or enters the at least one processing module.

5. The substrate processing system of claim 1, wherein the at least one sensor array further comprises a plurality of image sensors.

6. The substrate processing system of claim 1, wherein the at least one sensor array further comprises a plurality of laser sensors.

7. The substrate processing system of claim 6, wherein the plurality of laser sensors are at least one of temperature sensors or depth sensors.

8. The substrate processing system of claim 1, wherein the at least one sensor array is configured to measure at least one of: a height, a reflection rate, or a temperature of the substrate.

9. A method of measuring a state of a substrate in a substrate processing system, the method comprising:
providing at least one sensor array in at least one chamber of the substrate processing system;
when the substrate passes under the at least one sensor array, capturing substrate data indicative of the state of the substrate at each coordinate at a given time;
utilizing the coordinate data to determine the state of the substrate along a single dimension during a given time period;
converting the substrate data received from each sensor in the at least one sensory array along the single dimension to determine the state of the substrate as a whole; and
determining whether a condition should be altered based on the state of the substrate.

10. The method of claim 9, wherein providing the at least one sensor array comprises providing at least one of a 1D image sensor, a laser temperature sensor or a laser depth sensor.

11. The method of claim 9, wherein providing at least one sensor array in at least one chamber of the substrate processing system further comprises at least one of:
providing at least one sensor array in an equipment front end module (EFEM) aligned with an EFEM gate valve;
providing at least one sensor array in a substrate handling chamber (SHC) aligned with a SHC gate valve; or
providing at least one sensor array in a SHC aligned with a processing module gate valve.

12. The method of claim 9, wherein determining whether a condition should be altered based on the state of the substrate comprises at least one of:
altering a process condition based on the state of the substrate; or
adjusting speed of at least one of an EFEM robot or a SHC robot based on the state of the substrate.

13. The method of claim 9, wherein capturing substrate data indicative of the state of the substrate at each coordinate at a given time comprises at least one of:
capturing data indicative of height of the substrate;
capturing data indicative of reflection rate of the substrate; and
capturing data indicative of temperature of the substrate.

14. The method of claim 9, wherein the at least one sensor array comprises a plurality of sensor arrays.

15. The method of claim 9, wherein capturing substrate data indicative of the state of the substrate at each coordinate at a given time further comprises capturing substrate data indicative of the state of a processed substrate, wherein the processed substrate has been processed in a processing module of the substrate processing module.

16. A non-transitory computer-readable medium for determining state of a substrate transferring in a substrate processing system, comprising instructions stored thereon, that when executed on a processor, perform the steps of:
receiving substrate data from a sensor array provided in at least one chamber of the substrate processing system, the substrate data indicative of the state of the substrate at each coordinate at a given time;
determining the state of the substrate data along a single dimension during a given time period, the given time period include the given time; and
extrapolating the substrate data received from each sensor in the at least one sensory array along the single dimension to determine a state of the substrate as a whole.

17. The non-transitory computer readable medium of claim 16, wherein receiving substrate data indicative of the state of the substrate at each coordinate at a given time further comprises at least one of:
receiving data indicative of height of the substrate;
receiving data indicative of reflection rate of the substrate; and
receiving data indicative of temperature of the substrate.

18. The non-transitory computer readable medium of claim 16, wherein receiving substrate data from a sensory array further comprises receiving the substrate day from at least one a 1D image sensor, a laser temperature sensor or a laser depth sensor.

19. The non-transitory computer readable medium of claim 16, wherein receiving substrate data indicative of the state of the substrate at each coordinate at a given time further comprises at least one of:
receiving substrate data indicative of the state of the substrate before the substrate transfers from an EFEM of the substrate processing system to a load lock chamber of the substrate processing system;
receiving substrate data indicative of the state of the substrate before the substrate transfers from the load lock chamber to a substrate handling chamber of the substrate processing system; or
receiving substrate data indicative of the state of the substrate before the substrate transfers from the substrate handling chamber to a processing module of the substrate processing system.

20. A non-transitory computer-readable medium for determining state of a substrate transferring in a substrate processing system, further comprising instructions stored thereon, that when executed on a processor, perform the steps of at least one of:
determining alteration of a process condition based on the state of the substrate; or
determining adjustment of speed of at least one of an EFEM robot or a SHC robot based on the state of the substrate.
